(19) United States
(12) Patent Application Publication
(10) Pub. No.: US 2025/0022706 A1
(43) Pub. Date: Jan. 16, 2025

(54) SUBSTRATE PROCESSING METHOD AND SUBSTRATE PROCESSING APPARATUS

(71) Applicant: Tokyo Electron Limited, Tokyo (JP)

(72) Inventors: Tomohiko NIIZEKI, Miyagi (JP); Maju TOMURA, Miyagi (JP); Yoshihide KIHARA, Miyagi (JP)

(73) Assignee: Tokyo Electron Limited, Tokyo (JP)

(21) Appl. No.: 18/901,627

(22) Filed: Sep. 30, 2024

Related U.S. Application Data
(63) Continuation of application No. 17/128,215, filed on Dec. 21, 2020.

(30) Foreign Application Priority Data
Dec. 25, 2019 (JP) 2019-234124

(51) Int. Cl. H01L 21/02; C23C 16/455; C23C 16/50; C23C 16/52; H01L 21/3065; H01L 21/67; H10B 41/27; H10B 43/27

(52) U.S. Cl. CPC H01L 21/0228; C23C 16/45544; C23C 16/50; C23C 16/52; H01L 21/30655; H01L 21/67069; H10B 41/27; H10B 43/27

(57) ABSTRACT

A substrate processing method suppresses a shape abnormality of a pattern formed on a substrate. The substrate processing method executed by a substrate processing apparatus includes step a), step b), and step c). The step a) is a step of providing a substrate including an etching target film and a mask layer formed on the etching target film in which the mask layer has an opening. The step b) is a step of forming a protective film on an upper portion of an opening of the mask. The step c) is a step of etching the mask while suppressing a variation of an opening dimension of the upper portion of the opening by the protective film, and varying a dimension of a lower portion of the opening not covered by the protective film.

### CROSS-REFERENCE TO RELATED APPLICATIONS

This application is a continuation application of U.S. patent application Ser. No. 17/128,215, filed on Dec. 21, 2020, which claims priority from Japanese Patent Application No. 2019-234124, filed on Dec. 25, 2019, with the Japan Patent Office, all of each are incorporated herein in their entireties by reference.

### TECHNICAL FIELD

The following disclosure relates to a substrate processing method and a substrate processing apparatus.

### BACKGROUND ART

Integration of semiconductor devices progresses not only in a horizontal direction but also in a vertical direction. An aspect ratio of a pattern formed in a manufacturing process of the semiconductor device is also increased. For example, in the manufacture of 3D NAND, a channel hole is formed in a direction that penetrates many metal wiring layers. In forming a 64-layer memory cell, the aspect ratio of the channel hole becomes 45.

Various methods have been proposed to form a pattern having a high aspect ratio with high accuracy. For example, a method of suppressing a lateral etching by repeating etching and film formation on a recess formed in a dielectric material of a semiconductor substrate has been proposed (U.S. Patent Application Publication No. 2016/0343580).

### SUMMARY

A substrate processing method according to an aspect of the disclosure includes step a), step b), and step c). The step a) is a step of providing a substrate including an etching target film and a mask layer on the etching target film. The mask layer has an opening. The step b) is a step of forming a protective film on the upper portion of an opening in the mask layer. The step c) is a step of etching the mask layer while suppressing a variation of an opening dimension of the upper portion of the opening by the protective film and varying a dimension of a lower portion of the opening not covered with the protective film.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

FIG. 1 is a flowchart illustrating an example of a flow of a substrate processing method according to the embodiment.

FIG. 2A is a diagram for describing an example of a workpiece to be processed by the substrate processing method according to the embodiment.

FIG. 2B is a diagram for describing an example of the workpiece to be processed by the substrate processing method according to the embodiment.

FIG. 2C is a diagram for describing an example of the workpiece to be processed by the substrate processing method according to the embodiment.

FIG. 2D is a diagram for describing an example of the workpiece to be processed by the substrate processing method according to the embodiment.

FIG. 3A is a diagram for describing Processing Example 1 for forming a protective film according to the embodiment.

FIG. 3B is a diagram for describing Processing Example 1 for forming the protective film according to the embodiment.

FIG. 3C is a diagram for describing Processing Example 1 for forming the protective film according to the embodiment.

FIG. 3D is a diagram for describing Processing Example 1 for forming the protective film according to the embodiment.

FIG. 4A is a diagram for describing Processing Example 2 for forming the protective film according to the embodiment.

FIG. 4B is a diagram for describing Processing Example 2 for forming the protective film according to the embodiment.

FIG. 4C is a diagram for describing Processing Example 2 for forming the protective film according to the embodiment.

FIG. 5 is a flowchart illustrating another example of the flow of the substrate processing method according to the embodiment.

FIG. 6A is a diagram for describing a shape 1 formed by the substrate processing method according to the embodiment.

FIG. 6B is a diagram for describing the shape 1 formed by the substrate processing method according to the embodiment.

FIG. 6C is a diagram for describing the shape 1 formed by the substrate processing method according to the embodiment.

FIG. 6D is a diagram for describing the shape 1 formed by the substrate processing method according to the embodiment.

FIG. 6E is a diagram for describing the shape 1 formed by the substrate processing method according to the embodiment.

FIG. 7A is a diagram for describing a shape 2 formed by the substrate processing method according to the embodiment.

FIG. 7B is a diagram for describing the shape 2 formed by the substrate processing method according to the embodiment.

FIG. 7C is a diagram for describing the shape 2 formed by the substrate processing method according to the embodiment.

FIG. 7D is a diagram for describing the shape 2 formed by the substrate processing method according to the embodiment.

FIG. 7E is a diagram for describing the shape 2 formed by the substrate processing method according to the embodiment.

FIG. 8 is a diagram illustrating an example of a schematic configuration of a substrate processing apparatus according to the embodiment.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In the following description, a “pattern” refers to all shapes formed on a substrate. A pattern refers to all of a plurality of shapes formed on the substrate, for example, holes, trenches, lines and spaces, and the like. In addition, an “opening” refers to a portion of the pattern formed on the substrate, which has a shape recessed in a thickness direction of the substrate, also called as a “recess.” In addition, the opening has a “side wall” which is an inner peripheral surface having a recessed shape, a “bottom portion” which is a bottom portion of the recessed shape, and a “top portion” which is a substrate surface that is continuous with the side wall and in the vicinity of the side wall. In addition, the horizontal dimension in the space formed by the opening are referred to as an “opening dimension.” The term “opening” is also used to refer to the entire space enclosed by the bottom portion and side walls or an arbitrary position in the space.

The “vertical direction” refers to the film thickness direction of a plurality of films formed on the substrate. The vertical direction is a direction substantially perpendicular to the substrate surface. The “horizontal direction” refers to a direction parallel to the substrate surface. The horizontal direction is substantially perpendicular to the vertical direction. In addition, neither the vertical direction nor the horizontal direction strictly refers to only one direction, but a certain error is allowable.

In recent years, attention has been paid to a technique for processing a hole having a high aspect ratio in a semiconductor manufacturing technique. As an example, there is a high aspect ratio contact (HARC). The HARC is used for a dynamic random access memory (DRAM) and a three-dimensional NAND (3D-NAND). The aspect ratio of the HARC used for the DRAM is, for example, 45, and the aspect ratio of the HARC used for the 3D-NAND exceeds 65.

In the processing of the HARC, for example, a silicon oxide film, an amorphous carbon layer (ACL), a silicon oxynitride film (SiON), a bottom anti-reflection coating (BARC) film, and a photoresist are stacked on the substrate. After that, the pattern transferred to the photoresist is sequentially transferred to the lower layers to form a pattern. However, in a case where the hole has a high aspect ratio, it is difficult to form the hole perpendicular to the vertical direction. For example, a phenomenon known as bowing, in which the center of the hole in the vertical direction protrudes in the horizontal direction, has been known. In addition, a phenomenon in which the hole gradually becomes smaller (tapered) toward the bottom portion of the hole has also been known.

### EMBODIMENT

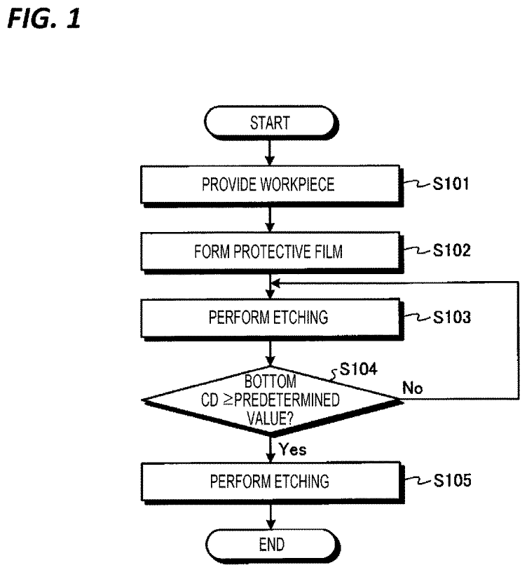

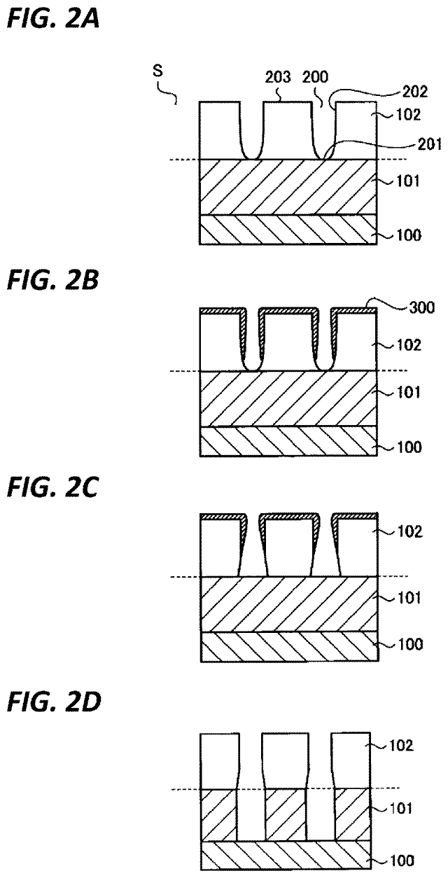

A substrate processing method according to an embodiment suppresses a shape abnormality of a pattern formed on a substrate, such as bowing or tapered shape. In addition, according to the substrate processing method according to the embodiment, the degree of freedom in controlling the shape of the pattern to be formed may be improved. FIG. 1 is a flowchart illustrating an example of a flow of the substrate processing method according to the embodiment. FIGS. 2A to 2D are diagrams illustrating an example of the workpiece to be processed by the substrate processing method according to the embodiment.

First, a workpiece S (see FIG. 2A) is provided (step S101). The workpiece S includes a substrate 100, an etching target film 101 formed on the substrate 100, and a mask layer 102 (see FIG. 2A). The mask layer 102 has an opening 200. The opening 200 has a bottom portion 201 and a side wall 202.

Next, a protective film 300 is formed on the mask layer 102 (step S102). The protective film 300 is formed on a top portion 203 and the side wall 202 of the opening 200. In the example of FIG. 2B, the protective film 300 is formed so that the film thickness thereof gradually decreases from the upper side of the side wall 202 toward the lower side thereof. A method for forming the protective film 300 will be described later.

Next, the mask layer 102 on which the protective film 300 is formed is etched (trimmed) (step S103). At this time, the portion of the side wall 202 covered by the protective film 300 is not etched, and the lower portion which is not covered or where the protective film 300 is thinner than the upper portion is increased in width by etching as compared with the upper portion (see FIG. 2C). There may be a step of determining whether or not the dimension (horizontal dimension) of the bottom portion 201 of the opening 200 is equal to or more than a predetermined value (step S104). The dimension of the bottom portion 201 is also called a bottom critical dimension (CD). In a case where it is determined in step S104 that the bottom CD of the opening 200 is not equal to or more than the predetermined value (NO in step S104), the process returns to step S103. Meanwhile, in a case where it is determined that the bottom CD of the opening 200 is equal to or more than the predetermined value (YES in step S104), the etching target film 101 is etched (step S105). Then, the process ends. The shape of the opening 200 changes as illustrated in FIG. 2D.

As described above, in the substrate processing method according to the embodiment, since the protective film 300 is formed on the side wall 202 so that the film thickness decreases from the upper side toward the lower side, the decrease of the bottom CD in the mask layer 102 is suppressed. For this reason, it is possible to suppress the shape abnormality of the pattern in the etching target film 101 due to the shape of the mask layer 102.

In addition, in the substrate processing method according to the embodiment, the protective film 300 may be formed even when the etching target film 101 is etched. Therefore, it is possible to suppress bowing. Furthermore, since the protective film 300 may be formed so that the film thickness decreases from the upper side toward the lower side, the decrease in the bottom CD of the opening 200 in the etching target film 101 may be suppressed.

### (Determination of Bottom CD)

The method of determination in step S104 is not limited. For example, the bottom CD may be determined by inspecting the shape of the workpiece S by an optical means or the like. In addition, the bottom CD may be determined based on the number of times of execution or the execution time of at least one of step S102 and step S103. The “predetermined value” in step S104 is set in advance based on a design value.

### (Determination of Necessity of Forming Protective Film)

The necessity of forming a protective film may be determined. A method of the determination is not particularly limited. For example, the necessity of forming the protective film 300 may be determined according to the thickness and/or the location of the protective film 300 remaining on the side wall 202. In addition, for example, the necessity of forming the protective film 300 may be determined according to the number of times of execution or the execution time of at least one of step S102 and step S103.

In addition, step S104 and the determination of necessity of forming the protective film may be collectively performed. For example, the process may be ended in a case where the number of times of execution of steps S102 and S103 reaches a value V1. In addition, the protective film 300 may be formed in a case where the number of times of execution of steps S102 and S103 is less than a value V2 (V2<V1). In addition, in a case where the number of times of execution of steps S102 and S103 is less than a value V3 (V3<V2), the etching (step S103) may be executed without forming the protective film 300.

### (Type of Film)

A type of each of the etching target film 101, the mask layer 102, and the protective film 300 is not particularly limited. For example, the substrate 100 may be a silicon wafer. The etching target film 101 may be a dielectric film, for example, a silicon-containing dielectric film. The etching target film 101 may be formed by stacking a plurality of types of films. For example, the etching target film 101 may be a layer in which a silicon oxide film and a silicon nitride film are sequentially stacked. The etching target film 101 may be a layer in which a silicon oxide film and a polysilicon film are sequentially stacked. The mask layer 102 may be a carbon-containing film. The carbon-containing film may be formed as an amorphous carbon layer (ACL) or a spin-on carbon film (SOC). Alternatively, the mask layer 102 may be formed as a metal film. Although not illustrated in FIGS. 2A to 2D, a silicon oxynitride film (SiON) or a bottom antireflection coating (BARC) having an opening pattern similar to that of the mask layer 102 may exist on the mask layer 102. The protective film 300 may be a silicon-containing film.

In the substrate processing method according to the embodiment, in a case where the etching target film 101 is a silicon-containing dielectric film, the protective film may be a carbon-containing film of ACL, SOC, or the like. In addition, in a case where the etching target film 101 is a polysilicon film, the protective film may be a silicon oxide film formed by using TEOS (tetraethoxysilane).

### (Method for Forming Protective Film)

The method for forming the protective film 300 is not particularly limited. For example, atomic layer deposition (ALD), subconformal ALD, chemical vapor deposition (CVD), physical vapor deposition (PVD), molecular layer deposition (MLD), and the like may be used. The process of step S102 may be realized by any one of the ALD, the subconformal ALD, the CVD, the PVD, the MLD, or a combination of a plurality thereof. In addition, in a case where the protective film 300 is formed on the upper side of the side wall 202 of the opening 200 more than on the lower side of the side wall 202, step S102 may be realized by any one of CVD and subconformal ALD, or a combination of a plurality of processes including any one thereof.

### Example 1 of Film Forming Method-Subconformal Atomic Layer Deposition (ALD)

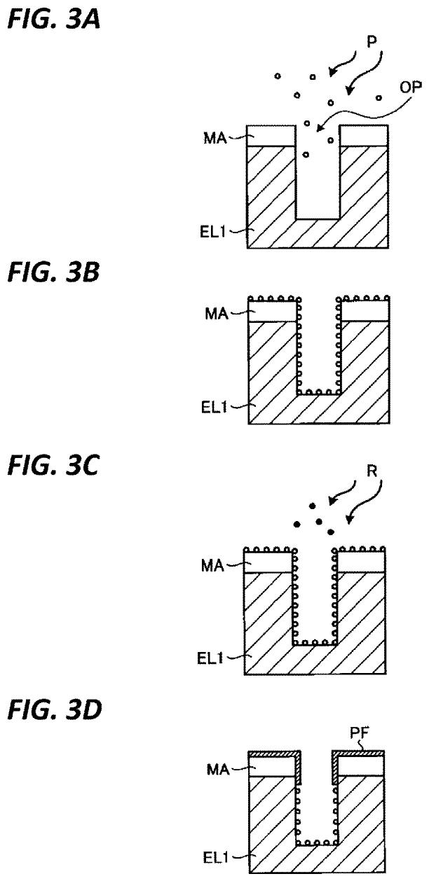

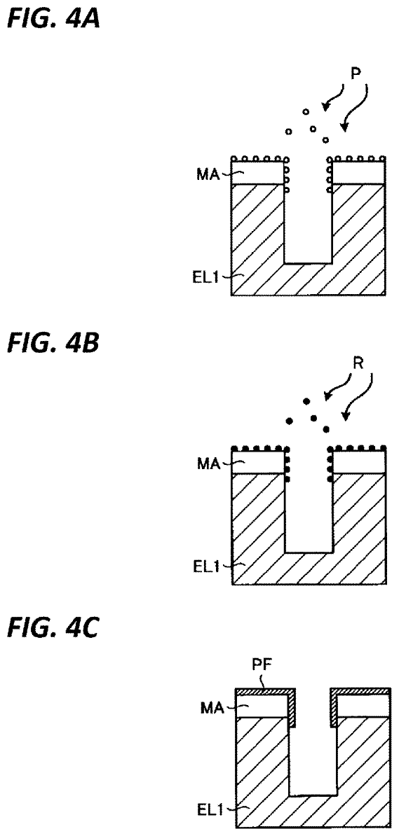

Next, the subconformal ALD will be described. FIGS. 3A to 3D are diagrams for describing Processing Example 1 for forming the protective film 300 according to the embodiment. In addition, FIGS. 4A to 4C are diagrams for describing Processing Example 2 for forming the protective film 300 according to the embodiment.

Before describing the subconformal ALD, conventional ALD will be described. The ALD generally includes four steps. First, in a first step, a first gas (also called a precursor or a first reactant) is introduced into a chamber (processing container) in which a workpiece is arranged. At this time, plasma may be generated from the first gas. The first material contained in the first gas is adsorbed on the surface of the workpiece. After the surface is covered with the first material, the chamber is evacuated (second step: purging). Next, a second gas (also referred to as a reaction gas or a second reactant) containing a second material that reacts with the first material is introduced into the chamber. At this time, plasma may be generated from the second gas. The second material reacts with the first material on the workpiece to form a film. In the ALD, a film is formed by adsorbing and reacting a predetermined material to a substance existing on the surface of the workpiece in a self-regulating manner. For this reason, in the ALD, generally, conformal film formation is realized by providing a sufficient processing time.

On the contrary, in the subconformal ALD, the processing conditions are set so that the adsorption or reaction in a self-regulating manner on the surface of the workpiece is not completed. There are at least two processing modes as follows.

(1) The precursor is adsorbed on the entire surface of the workpiece. The reaction gas introduced thereafter is controlled so as not to cover the entire surface of the precursor adsorbed on the workpiece.

(2) The precursor is adsorbed only on a portion of the surface of the workpiece. The reaction gas introduced thereafter is reacted only with the precursor adsorbed on the surface of the workpiece.

In the substrate processing method according to the embodiment, the method of (1) or (2) is used to form a film of which film thickness decreases along the thickness direction on the side wall of the opening that the mask layer has.

FIGS. 3A to 3D illustrate the processing mode (1). The workpiece illustrated in FIG. 3A includes an etching target film ELI formed on a substrate (not illustrated) and a mask MA. An opening OP is formed in the mask MA.

First, a precursor P is introduced into the chamber in which the workpiece is disposed (FIG. 3A). By providing a sufficient processing time for adsorption of the precursor P, the precursor P is adsorbed on the entire surface of the workpiece (FIG. 3B). The precursor P may be turned into plasma to be adsorbed. When the adsorption of the precursor P is completed, the chamber is purged (optionally). Next, reaction gas R is introduced into the chamber (FIG. 3C). The reaction gas R may be turned into plasma. The introduced reaction gas R reacts with the precursor P on the workpiece, and thus, the film formation gradually progresses from above the mask MA. Herein, before the film formation reaches below the mask MA, the reaction gas R is purged (optionally). By carrying out such a treatment, a film may be formed on a portion of the side wall of the opening of the mask MA (FIG. 3D). The portion denotes, for example, the upper portion of the opening.

FIGS. 4A to 4C illustrate the processing mode (2). The workpiece illustrated in FIG. 4A has the same shape as that of FIG. 3A. In the example of FIG. 4A, the precursor P is adsorbed only on the upper portion of the workpiece. For example, the precursor P is adsorbed by CVD. Similarly to the processing mode (1), the precursor P may be turned into plasma. After the precursor P is purged, the reaction gas R is introduced into the chamber (FIG. 4B). The reaction gas R may be turned into plasma. At this time, the reaction gas R reacts only at the location where the precursor P is adsorbed to form a film, so that the film is formed only above the workpiece (FIG. 4C).

As described above, in the subconformal ALD, the adsorption of the precursor in Processing Example 2 or the reaction of the reaction gas in Processing Example 1 is allowed to occur imitatively in a predetermined portion of the workpiece. For example, the film is formed only on the upper portion of the side wall of the opening. The processing parameters to be adjusted for the location-selective film formation are, for example, a temperature of the mounting stand on which the workpiece is mounted, a pressure in the chamber, a gas flow rate of the reaction gas to be introduced, a pressure, a processing time, and the like. In addition, in the case of processing using plasma, the location of the film formation may also be adjusted by adjusting the value of radio frequency (RF) power applied to generate plasma.

In the substrate processing method according to the embodiment, the shape of the opening 200 formed by etching is controlled by controlling the location and thickness of the protective film 300 on the side wall 202.

### (Shape Example)

In FIGS. 2A to 2D, a case where holes having substantially the same opening dimensions from the upper side to the lower side are formed in the etching target film 101 has been described. Not limited thereto, the substrate processing method according to the embodiment may also be used for the case of forming holes having a tapered shape. By the substrate processing method according to the embodiment, for example, holes having a forward tapered shape and holes having an inverse tapered shape may be formed.

### Shape Example 1—Taper

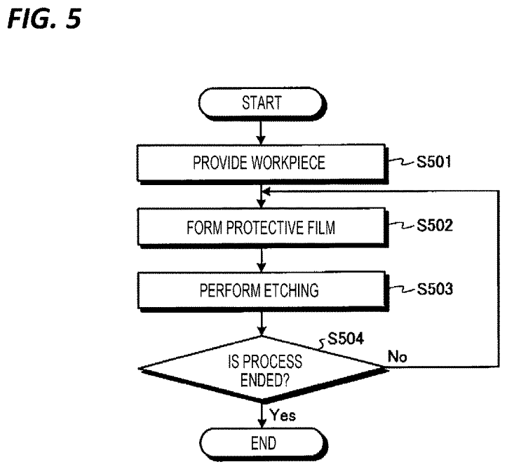

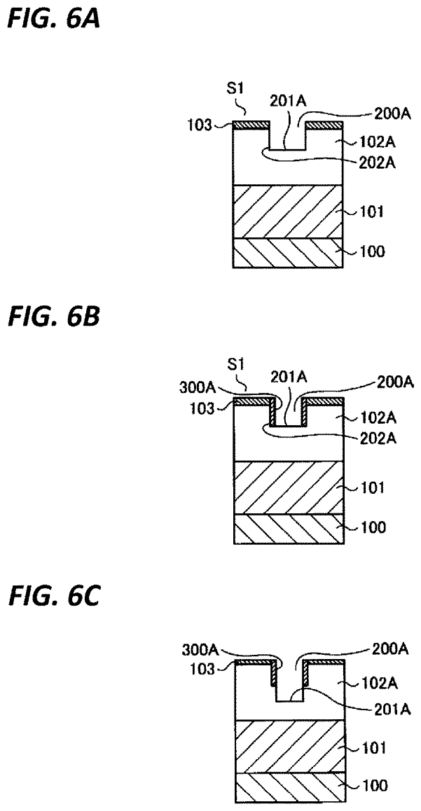

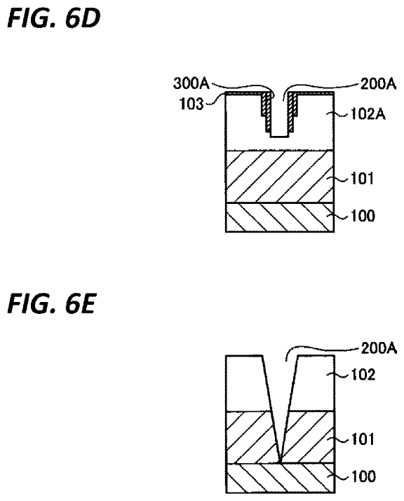

FIG. 5 is a flowchart illustrating another example of the flow of the substrate processing method according to the embodiment. FIGS. 6A to 6E are diagrams for describing the shape 1 (forward taper) formed by the substrate processing method according to the embodiment. The forward tapered shape denotes the shape of a hole that gradually tapers from the upper side toward the lower side.

The flow illustrated in FIG. 5 is almost the same as the flow illustrated in FIG. 1. Steps S501 to S503 in FIG. 5 correspond to steps S101 to S103 in FIG. 1. Step S504 of FIG. 5 is a step of determining whether or not to end the process. Whether or not to end the process is determined based on, for example, whether or not the aspect ratio of the opening formed in the workpiece has reached a predetermined value. Whether or not to end the process may be determined based on whether or not the number of times of execution of steps S502 and S503 reaches a threshold value.

In a workpiece S1 illustrated in FIG. 6A, an etching target film 101, a mask layer 102A, and a second mask 103 are formed on mask layer 102A. In addition, an opening 200A is formed in the mask layer 102A and the second mask 103. First, the workpiece S1 is provided (step S501 in FIG. 5). Next, a protective film 300A is formed on a side wall 202A of the opening 200A (step S502 in FIG. 5). In the example of FIG. 6B, the protective film 300A is formed so as to cover the entire surface of the side wall 202A with substantially the same film thickness. For example, the protective film 300A is formed by the ALD. Next, the workpiece S1 is etched (step S503 in FIG. 5). The aspect ratio of the opening 200A is increased by the etching. The lower side of the side wall 202A of the opening 200A is not covered with the protective film 300A (see FIG. 6C).

Next, it is determined whether or not the processing is to be ended (step S504 in FIG. 5). The criterion is, for example, whether or not the aspect ratio has reached a predetermined value. In the example of FIG. 6C, since the aspect ratio of the opening 200A has not reached the predetermined value, it is determined that the processing is not to be ended (NO in step S504 in FIG. 5), and the process returns to step S502. After forming the protective film 300A in step S502, etching is performed (see FIG. 6D).

As described above, while the protective film 300A is formed on the entire side wall 202A of the opening 200A, the opening 200A is dug forward, and the shape of the opening 200A becomes a forward tapered shape that is gradually tapered from the upper portion toward the lower portion.

When the etching target film 101 is etched through the mask layer 102 having a forward tapered shape, the shape of the mask layer 102 is transferred to the etching target film 101 and becomes a tapered shape that is tapered toward the bottom portion (FIG. 6E).

As described above, according to the substrate processing method according to the embodiment, the opening 200A may be gradually deepened while maintaining the shape of the side wall 202A of the opening 200A formed in advance. For this reason, it is possible to suppress the shape abnormality of the side wall 202A by the protective film 300A. In addition, according to the embodiment, the opening 200A having a forward tapered shape may be formed as illustrated in FIGS. 6A to 6E.

### Shape Example 2—Inverse Taper

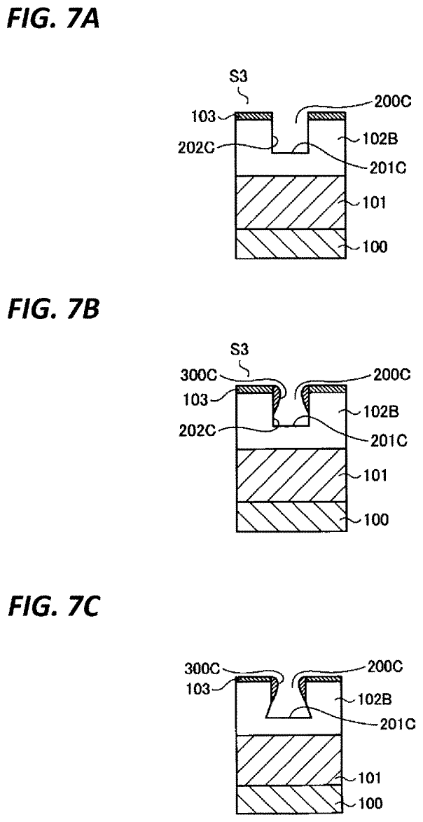

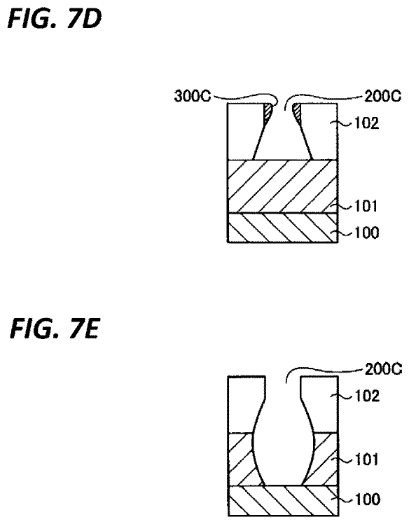

FIGS. 7A to 7E are diagrams for describing the shape 2 (inverse tapered shape) formed by the substrate processing method according to the embodiment. The inverse tapered shape denotes a shape of a hole of which the opening dimension gradually increases from the upper side to the lower side.

In a workpiece S3 illustrated in FIG. 7A, an etching target film 101, a mask layer 102B, and a second mask 103 are formed on the substrate 100. An opening 200C is formed in the mask layer 102B and the second mask 103. First, the workpiece S3 is provided (step S501 in FIG. 5).

Next, a protective film 300C is formed on a side wall 202C of the opening 200C (step S502 in FIG. 5). In the example of FIG. 7B, the protective film 300C is formed to have different film thicknesses on the upper side and the lower side of the side wall 202C. In the example of FIG. 7B, the protective film 300C is formed by, for example, CVD or subconformal ALD. In the example of FIG. 7B, the lower end of the protective film 300C is located above a bottom portion 201C. In addition, the protective film 300C is formed so that the lower end thereof is closer to the upper side than the protective film 300 (FIG. 2B).

Next, the workpiece S3 is etched (step S503 in FIG. 5). The aspect ratio of the opening 200C is increased by the etching. The lower portion of the side wall 202C of the opening 200C is not covered with the protective film 300C (see FIG. 7C). In addition, unlike the example of FIG. 6C, the horizontal dimension of the opening 200C of FIG. 7C gradually increases from the mask layer 102B side toward the etching target film 101 side.

At this point in time, the aspect ratio of the opening 200C has not reached the predetermined value, so it is determined that the processing is not to be ended (step S504, NO). Then, returning to step S502, the protective film 300C is formed. At this time, the protective film 300C is formed so that the film thickness gradually decreases from the upper portion toward the lower portion. Then, etching is performed.

As described above, while the protective film 300C is formed so that the film thickness gradually decreases from the upper side of the side wall 202C of the opening 200C toward the lower side and the lower end is located above the bottom portion 201C, the opening 200C continue to be dug forward. Then, the shape of the opening 200C becomes an inverse tapered shape gradually spreading in the horizontal direction from the upper side toward the lower side (FIG. 7D).

Next, when the etching target film 101 is etched, the shape illustrated in FIG. 7E is obtained. By repeating the etching while forming the protective film 300C also during the etching of the etching target film 101, the shape of the opening in the etching target film 101 may be set to an inverse taper similarly to the shape of the opening in the mask layer 102.

In the shape 2, the protective film 300C is formed so that the thickness of the protective film 300C differs depending on the location of the opening 200C. For this reason, the protective film 300C may be set to be thick at the location where bowing is easy to occur, and the protective film 300C may be set to be thin in the vicinity of the bottom portion 201C of the opening 200C where ions and radicals are hard to reach. For this reason, with the substrate processing method according to the embodiment, it is possible to suppress the bottom CD from decreasing while suppressing bowing. In addition, in the shape 2, the protective film 300C having a larger film thickness on the upper side is formed as compared with the protective film 300 (FIG. 2B). In addition, the protective film 300C is formed so that the lower end is located above the bottom portion 201C. For this reason, as compared with the example of FIG. 2B, the effect of etching in the bottom portion 201C of the opening 200C is stronger in the shape 2. For this reason, the opening 200C having an inverse tapered shape may be formed.

As described above, according to the substrate processing method according to the embodiment, it is possible to gradually deepen the opening 200C while maintaining the shape of the side wall 202C of the opening 200C formed in advance. In addition, by setting the thickness of the protective film 300C to be small in the vicinity of the bottom portion 201C of the opening 200C in which the influence of ions and radicals is weakened, the etching effect may be sufficiently exerted on the bottom portion 201C of the opening 200C.

As described above, according to the embodiment, by adjusting the location and thickness of the protective film, it is possible to form openings having various shapes such as a forward taper, a vertical hole, and an inverse taper.

### (Correction of Mask)

In addition, the substrate processing method according to the above-described embodiment may be used to suppress any shape abnormality of the masks 102 (mask layers 102A and 102B) and the etching target film 101.

In a case where the shape abnormality of the mask layer 102 occurs once, it may be considered to perform the shape correction by forming a film on a place where the shape abnormality occurs. However, in this case, the material used for the shape correction of the mask layer 102 and the material of the etching target film 101 may be of the same kind of material. In this case, during the etching of the etching target film 101, the material used for the shape correction may be similarly scraped, and the shape of the mask layer 102 may be distorted. For this reason, the material constituting the mask layer 102 may be made of a single material. Thus, the material of the protective film may be selected so that the material constituting the mask layer 102 is single. In this way, the substrate processing method according to the above-described embodiment is advantageous in that it is possible to suppress the occurrence of the shape abnormality of the mask layer 102.

In addition, the substrate processing method according to the embodiment may or may not use plasma in forming the protective film in step S102 and etching in step S103.

### (Configuration Example of Substrate Processing Apparatus)

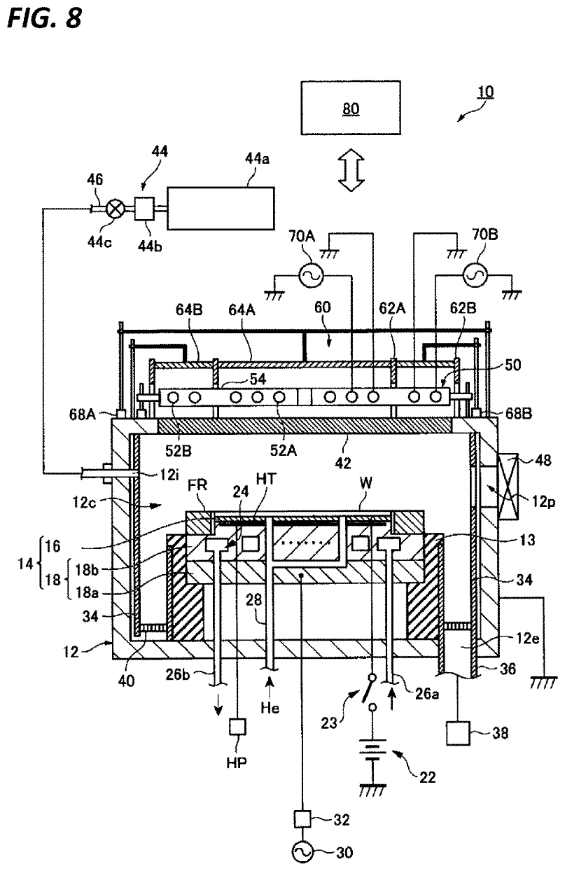

FIG. 8 is a diagram illustrating a schematic configuration of a substrate processing apparatus 10 according to the embodiment. The substrate processing apparatus 10 illustrated in FIG. 8 may be used to realize the substrate processing method according to the embodiment. The substrate processing apparatus 10 illustrated in FIG. 8 is a inductively-coupled plasma (ICP) apparatus and has a plasma source for generating inductively coupled plasma. However, the substrate processing apparatus according to the embodiment may use plasma generated by other methods. For example, the substrate processing apparatus according to the embodiment may be an apparatus using capacitively-coupled plasma (CCP), electron-cyclotron-resonance plasma (ECR plasma), helicon wave excited plasma (HWP), surface wave plasma (SWP), or the like.

The substrate processing apparatus 10 includes a chamber 12. The chamber 12 is made of metal such as aluminum. The chamber 12 has, for example, a substantially cylindrical shape. A space 12c in which processing is executed is provided inside the chamber 12.

A substrate support base 14 is arranged below the space 12c. The substrate support base 14 is configured to hold a substrate W mounted thereon. The substrate W is, for example, a substrate which is to be processed by the method according to the embodiment.

The substrate support base 14 may be supported by a support mechanism 13. The support mechanism 13 extends upward from the bottom portion of the chamber 12 inside the space 12c. The support mechanism 13 may have a substantially cylindrical shape. The support mechanism 13 may be made of an insulating material such as quartz.

The substrate support base 14 includes an electrostatic chuck 16 and a lower electrode 18. The lower electrode 18 includes a first plate 18a and a second plate 18b. The first plate 18a and the second plate 18b are made of a metal such as aluminum. The first plate 18a and the second plate 18b have, for example, a substantially cylindrical shape. The second plate 18b is arranged on the first plate 18a. The second plate 18b is electrically connected to the first plate 18a.

The electrostatic chuck 16 is arranged on the second plate 18b. The electrostatic chuck 16 includes an insulating layer and a thin film electrode arranged inside the insulating layer. A DC power supply 22 is electrically connected to the thin film electrode of the electrostatic chuck 16 through a switch 23. The electrostatic chuck 16 generates an electrostatic force from a DC voltage of the DC power supply 22. The electrostatic chuck 16 attracts and holds the substrate W by the generated electrostatic force.

An edge ring FR is arranged on the second plate 18b and around the second plate 18b so as to surround the outer periphery of the substrate W and the electrostatic chuck 16 during the operation of the substrate processing apparatus 10. The edge ring FR has a function of improving uniformity of process. The edge ring FR is made of, for example, silicon.

A flow channel 24 is formed in the second plate 18b. A heat exchange medium such as a cooling medium for temperature control is supplied to the flow channel 24 from a temperature adjusting unit (for example, a chiller unit) arranged outside the chamber 12. The temperature adjusting unit adjusts the temperature of the heat exchange medium.

The heat exchange medium is supplied to the flow channel 24 from the temperature adjusting unit via a pipe 26a. The heat exchange medium supplied from the temperature adjusting unit to the flow channel 24 via the pipe 26a is then sent back to the temperature adjusting unit via a pipe 26b. The heat exchange medium is returned to the flow channel 24 in the substrate support base 14 after the temperature is adjusted by the temperature adjusting unit. By doing so, it is possible to adjust the temperature of the substrate support base 14, that is, the temperature of the substrate W.

The substrate processing apparatus 10 further includes a gas supply line 28 that extends through the substrate support base 14 toward the upper surface of the electrostatic chuck 16. A heat exchange gas such as helium (He) gas is supplied to the space between the upper surface of the electrostatic chuck 16 and the lower surface of the substrate W from a heat exchange gas supply mechanism through the gas supply line 28. By doing so, heat exchange between the substrate support base 14 and the substrate W is promoted.

In addition, a heater HT may be arranged in the substrate support base 14. The heater HT is a heating device. The heater HT is buried, for example, in the second plate 18b or the electrostatic chuck 16. The heater HT is connected to a heater power supply HP. The heater power supply HP supplies a power to the heater HT, so that the temperature of the substrate support base 14 and thus the temperature of the substrate W are adjusted.

A radio frequency (RF) power supply 30 is connected to the lower electrode 18 of the substrate support base 14 through a matching unit 32. An RF current may be supplied from the RF power supply 30 to the lower electrode 18. The RF power supply 30 generates an RF power to attract ions to the substrate W mounted on the substrate support base 14. That is, the RF power supply 30 generates an RF current that becomes a bias voltage. The frequency of the RF current generated by the RF power supply 30 is, for example, in the range of 400 kHz to 40.68 MHz. In one example, the frequency of the RF current is 13.56 MHz.

The substrate processing apparatus 10 further includes a shield 34 that is detachably attached to an inner wall of the chamber 12. The shield 34 is also arranged so as to surround the outer periphery of the support mechanism 13. The shield 34 prevents adhesion of by-products produced by the process to the chamber 12. The shield 34 may be an aluminum member that is coated with a ceramic such as Y2O3.

An exhaust passage is formed between the substrate support base 14 and the side wall of the chamber 12. The exhaust passage is connected to an exhaust port 12e formed at the bottom portion of the chamber 12. The exhaust port 12e is connected to an exhaust device 38 through a pipe 36. The exhaust device 38 includes a pressure adjusting unit and a vacuum pump such as a turbo molecular pump (TMP). A baffle plate 40 is arranged in the exhaust passage, that is, between the substrate support base 14 and the side wall of the chamber 12. The baffle plate 40 has a plurality of through holes penetrating the baffle plate 40 in the thickness direction. The baffle plate 40 may be an aluminum member of which surface is coated with a ceramic such as Y₂O₃.

An opening is formed on the upper side of the chamber 12. The opening is closed by a window 42. The window 42 is made of a dielectric material such as quartz. The window 42 is, for example, a flat plate.

An intake port 12i is formed on the side wall of the chamber 12. The intake port 12i is connected to a gas supply unit 44 through a pipe 46. The gas supply unit 44 supplies various gases used for processing to the space 12c. The gas supply unit 44 includes a plurality of gas sources 44a, a plurality of flow controllers 44b, and a plurality of valves 44c. Although not clearly illustrated in FIG. 8, a plurality of different intake ports may be provided for each gas to be supplied so that the gases are not mixed with each other.

The plurality of gas sources 44a include gas sources of various gases described below. One gas source may supply one or more gases. The plurality of flow controllers 44b may be mass flow controllers (MFCs), and the flow controller 44b realizes flow rate control by pressure control. Each gas source included in the plurality of gas sources 44a is connected to the intake port 12i through a corresponding one flow controller of the plurality of flow controllers 44b and a corresponding one valve of the plurality of valves 44c. The location of the intake port 12i is not particularly limited. For example, the intake port 12i may be formed in the window 42 instead of the side wall of the chamber 12.

An opening 12p is formed in the side wall of the chamber 12. The opening 12p serves as a loading/unloading path for the substrate W that is loaded into the space 12c of the chamber 12 from the outside and is unloaded from the space 12c to the outside of the chamber 12. A gate valve 48 is provided on the side wall of the chamber 12, so that the opening 12p may be opened and closed.

An antenna 50 and a shield 60 that covers the antenna 50 are arranged on the chamber 12 and the window 42. The antenna 50 and the shield 60 are arranged above the window 42 outside the chamber 12. In one embodiment, the antenna 50 includes an inner antenna element 52A and an outer antenna element 52B. The inner antenna element 52A is a spiral coil arranged in the center of the window 42. The outer antenna element 52B is a spiral coil arranged on the window 42 and on the outer peripheral side of the inner antenna element 52A. Each of the inner antenna element 52A and the outer antenna element 52B is made of a conductive material such as copper, aluminum, or stainless steel.

The inner antenna element 52A and the outer antenna element 52B are connected to an RF power supply 70A and an RF power supply 70B, respectively. The inner antenna element 52A and the outer antenna element 52B are supplied with powers having the same or different frequencies from the RF power supply 70A and the RF power supply 70B, respectively. When an RF power is supplied from the RF power supply 70A to the antenna 50, an induction magnetic field is generated in the space 12c and excites a processing gas in the space 12c to generate plasma above the substrate W.

The substrate processing apparatus 10 further includes a controller 80. The controller 80 may be a computing device including a processor, a storage unit such as a memory, an input unit, and a display. The controller 80 operates based on a control program and recipe data stored in the storage unit and controls each unit of the substrate processing apparatus 10. For example, the controller 80 controls the plurality of flow controllers 44b, the plurality of valves 44c, the exhaust device 38, the RF power supplies 70A and 70B, the RF power supply 30, the matching unit 32, the heater power supply HP, and the like. When implementing the substrate processing method according to the embodiment, the controller 80 may control each unit of the substrate processing apparatus 10 based on the control program and the recipe data.

### Effects of Embodiment

As described above, the substrate processing method according to the embodiment includes step a), step b), and step c). The step a) is a step of providing a substrate including an etching target film and a mask formed on the etching target film. The step b) is a step of forming a protective film on the upper portion of the opening of the mask. The step c) is a step of etching the mask while suppressing the variation of the opening dimension of the upper portion of the opening by the protective film and varying the dimension of the lower portion of the opening not covered with the protective film. For this reason, according to the embodiment, it is possible to suppress the shape abnormality of the pattern formed on the substrate.

In addition, in the substrate processing method according to the embodiment, in the step c), the dimension of the lower portion of the opening not covered with the protective film may be widened in at least one of the horizontal direction and the vertical direction. For this reason, according to the embodiment, in a case where a taper is generated from the upper side to the lower side of the opening, the horizontal dimension of the bottom portion may be widened.

In addition, in the substrate processing method according to the embodiment, in the step b), a protective film may be formed by any one of chemical vapor deposition (CVD), physical vapor deposition (PVD), atomic layer deposition (ALD), or a combination thereof. In addition, in the step b), in a case where the protective film is formed more on the upper side of the side wall of the opening than on the lower side of the side wall of the opening, the protective film may be formed by a combination of a plurality of processes including at least one of the CVD and the subconformal ALD, and in a case where the protective films are formed to the same extent on the upper side of the side wall and the lower side of the side wall of the opening, the protective film may be formed by the ALD. For this reason, it is possible to readily control the thickness of the protective film.

In addition, in the substrate processing method according to the embodiment, the step b) includes step b-1) and step b-2). The step b-1) is a step of supplying the first reactant and adsorbing the first reactant on the side wall of the opening. The step b-2) is a step of supplying the second reactant and reacting the first reactant and the second reactant to form a film. The step b-1) is completed before the first reactant is adsorbed on the entire surface of the side wall of the opening, or the step b-2) is completed before the second reactant constitutes a film on the entire surface of the side wall of the opening.

In addition, in the substrate processing method according to the embodiment, the step b) and the step c) are repeatedly performed. For this reason, it is possible to control the shape of the opening by appropriately performing protective film formation and etching in accordance with the state of the opening.

In addition, substrate processing method according to the embodiment may further include step d). The step d) is a step of further etching the etching target film subsequent to the step c).

In addition, in the substrate processing method according to the embodiment, the mask may include any one of an amorphous carbon layer (ACL), a spin-on carbon (SOC) film, and a metal film. As described above, the substrate processing method according to the embodiment may be used for forming the HARC used for a DRAM, a three-dimensional NAND, or the like.

In addition, the substrate processing apparatus according to the embodiment includes a chamber, a mounting stand, a gas supply unit, and a control unit. The chamber provides a processing space. The mounting stand is provided inside the chamber. The workpiece is mounted on the mounting stand. The gas supply unit supplies the processing gas into the chamber. The control unit allows each unit of the substrate processing apparatus to execute the substrate processing method. The substrate processing method includes step a), step b), and step c). The step a) is a step of providing a substrate including an etching target film and a mask formed on the etching target film. The step b) is a step of forming a protective film on the upper portion of the opening of the mask. The step c) is a step of etching the mask while suppressing the variation of the opening dimension of the upper portion of the opening by the protective film and varying the dimension of the lower portion of the opening not covered with the protective film.

According to the disclosure, it is possible to suppress the shape abnormality of a pattern formed on a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
a) providing a substrate including an etching target film and a mask layer formed on the etching target film, the mask layer having an opening;
b) forming a protective film on an upper portion of the opening of the mask layer; and
c) etching the mask layer while suppressing a variation of an opening dimension of the upper portion of the opening by the protective film, and varying a dimension of a lower portion of the opening not covered by the protective film.

2. The substrate processing method according to claim 1, wherein, in the c) of etching the mask layer, a dimension of the lower portion of the opening not covered by the protective film is widened in at least one of a horizontal direction and a vertical direction.

3. The substrate processing method according to claim 1, wherein, in the b) of forming the protective film, the protective film is formed by any one of chemical vapor deposition (CVD), physical vapor deposition (PVD) and atomic layer deposition (ALD), or a combination thereof.

4. The substrate processing method according to claim 1, wherein, in the b) of forming the protective film, in a case where the protective film is formed on an upper side of a side wall of the opening more than on a lower side of the side wall of the opening, the protective film is formed by a combination of a plurality of processes including at least one of the CVD and subconformal ALD, and in a case where the protective film is formed to the same extent on the upper side of the side wall of the opening and the lower side of the side wall of the opening, the protective film is formed by the ALD.

5. The substrate processing method according to claim 4,
wherein the b) of forming the protective film includes:
b-1) supplying a first reactant and adsorbing the first reactant on the side wall of the opening; and
b-2) supplying a second reactant and reacting the first reactant with the second reactant to form a film,
wherein the b-1) of supplying the first reactant and adsorbing of the first reactant is ended before the first reactant is adsorbed on the entire side wall of the opening, or
wherein the b-2) of supplying the second reactant and reacting of the first reactant with the second reactant is ended before the second reactant forms a film on the entire side wall of the opening.

6. The substrate processing method according to claim 1, wherein the b) of forming the protective film and the c) of etching the mask layer are repetitively executed.

7. The substrate processing method according to claim 1, further comprising, subsequently to the c) of etching the mask layer, d) etching the etching target film.

8. The substrate processing method according to claim 1, wherein the mask layer includes any one of an amorphous carbon layer (ACL), a spin-on-carbon (SOC) film, and a metal film.

9. A substrate processing apparatus comprising:
a chamber;
a substrate support base provided inside the chamber;
a gas supply for supplying a processing gas into the chamber;
a plasma generator; and
a controller,
wherein the controller is configured to execute a substrate processing method including:
a) receiving a substrate including an etching target film and a mask layer formed on the etching target film, the mask layer having an opening;
b) forming a protective film on an upper portion of the opening of the mask layer; and
c) etching the mask layer while suppressing a variation in an opening dimension of the upper portion of the opening by the protective film, and varying a dimension of a lower portion of the opening not covered by the protective film.
